(19) United States
(12) Patent Application Publication
(10) Pub. No.: US 2011/0055486 A1
(43) Pub. Date: Mar. 3, 2011

(54) RESISTIVE MEMORY DEVICES AND RELATED METHODS OF OPERATION

(75) Inventors: Seong-Moo HEO, Seoul (KR); Sang-Hoan CHANG, Suwon-si (KR)

(73) Assignee: SAMSUNG ELECTRONICS CO., LTD., Suwon-si (KR)

(21) Appl. No.: 12/859,459

(22) Filed: Aug. 19, 2010

(30) Foreign Application Priority Data
Sep. 1, 2009 (KR) 10-2009-0082030

(51) Int. Cl. G06F 12/08; G06F 12/00; G11C 11/00

(52) U.S. Cl. 711/128; 365/163; 365/148

(57) ABSTRACT

A method of processing data in a resistive memory device comprises performing a write operation to store data into a resistive memory of the resistive memory device and to store program information of the data into a cache memory. The method further comprises performing a first read operation to read the program information from the cache memory during a program-to-active time, and a second read operation to read the data from the resistive memory after the program-to-active time if the program information is not read from the cache memory during the program-to-active time.

### CROSS-REFERENCE TO RELATED APPLICATIONS

This application claims priority under 35 USC §119 to Korean Patent Application No. 10-2009-0082030 filed on Sep. 1, 2009, the disclosure of which is hereby incorporated by reference in its entirety.

### BACKGROUND

Embodiments of the inventive concept relate generally to memory devices, and more particularly, to resistive memory devices and related methods of operation.

Semiconductor memory devices can be roughly divided into two categories based on whether or not they retain stored data when disconnected from power. These categories include nonvolatile memory devices, which retain stored data when disconnected from power, and volatile memory devices, which lose stored data when disconnected from power. Examples of volatile memory devices include dynamic random access memory (DRAM) and static random access memory (SRAM), and examples of nonvolatile memory devices include flash memory devices and read only memory (ROM).

In recent years, increasing demand for high capacity, high performance, and low power nonvolatile data storage has led to the development of various new types of nonvolatile memory devices. For example, recent years have seen the development of phase change random access memories (PRAMs), which employ phase change materials, resistance random access memories (RRAMs), which employ materials having variable resistance such as transition-metal oxides, and magnetic random access memories (MRAMs), which employ ferromagnetic materials. Such materials have common characteristics in that resistances are varied based on the magnitude and/or direction of an applied voltage and/or current. Moreover, such resistances can be maintained even where power is cut off, so refresh operations are not required to retain stored data.

In a resistive memory, each memory cell comprises a variable resistance element, and a switching element to control a voltage or current applied to the variable resistance element. The variable resistance element is typically located between a bitline and the switching element, and the switching element is typically located between the variable resistance element and a wordline. Accordingly, a plurality of such memory cells arranged in a memory cell array can be controlled by applying voltages to a plurality of wordlines and bitlines connected to rows and columns of the array.

A PRAM comprises variable resistance elements comprising a phase change material such as Ge—Sb—Te (GST), which changes resistance in response to changes in temperature. An RRAM comprises a variable resistance element comprising an upper electrode, a lower electrode, and a complex metal oxide formed between the upper electrode and the lower electrode. An MRAM comprises a variable resistance element comprising an upper electrode of magnetic material, a lower electrode of magnetic material, and a dielectric material formed between the upper electrode and the lower electrode.

Many resistive memories, including PRAMs, experience a delay between execution of a program operation and a time when the written data can be accessed. In other words, a certain delay is required between a program operation used to store data in a resistive memory, and a read operation used to access the stored data. The delay phenomenon is referred to as resistance drift, and the delay time between the program operation and availability of the stored data is referred to as a program-to-active time (tPTA). In various conventional resistive memories, the tPTA has a value between about 1 us and about 100 us, which can significantly limit the performance of the resistive memories.

### SUMMARY

Selected embodiments of the inventive concept provide resistive memory devices and methods of processing data to account for resistance drift in the resistive memory devices.

According to one embodiment of the inventive concept, a method of processing data in a resistive memory device comprising a resistive memory is provided. The method comprises performing a write operation to store data into the resistive memory and to store program information corresponding to the data into a cache memory, performing a first read operation to read the program information from the cache memory during a program-to-active time in which the data is being stored in the resistive memory, and performing a second read operation to read the data from the resistive memory after the program-to-active time.

In certain embodiments, the cache memory is incorporated in a memory controller of the resistive memory device.

In certain embodiments, the cache memory is incorporated in a host.

In certain embodiments, the cache memory is a dynamic random access memory or a static random access memory.

In certain embodiments, the resistive memory is a phase-change random access memory.

In certain embodiments, performing the write operation comprises determining whether the cache memory is filled, upon determining that the cache memory is filled, storing the program information into a buffer, and upon determining that the cache memory is not filled, storing the program information into the cache memory.

In certain embodiments, performing the write operation comprises determining whether the cache memory is filled, upon determining that the cache memory is filled, storing the program information into a buffer, detecting expiration of an entry in the cache memory, and upon detecting the expiration of the entry, transferring the program information from the buffer to the cache memory.

In certain embodiments, the program information is transferred from the buffer to the cache memory using first-in first-out method.

In certain embodiments, the program information comprises a starting address of the resistive memory in which the data is to be stored, a number of words in the data, and the data.

In certain embodiments, performing the first read operation comprises determining whether the cache memory is filled and whether a first buffer is empty, and upon determining that the cache memory is filled and the first buffer is not empty, searching the first buffer for the program information.

In certain embodiments, performing the first read operation further comprises determining whether the program information is stored in the first buffer, and upon determining that the program information is stored in the first buffer, storing read information for the data in a second buffer.

In certain embodiments, performing the first read operation further comprises determining whether the program information is stored in the first buffer, and upon determining that the program information is not stored in the first buffer, searching the cache memory for the program information using a fully-associated method based on the starting address and the number of words.

In certain embodiments, performing the first read operation further comprises determining whether the program information is stored in the cache memory, upon determining that the program information is stored in the cache memory, reading the program information from the cache memory, and upon determining that the program information is not stored in the cache memory, reading the data from the resistive memory.

In certain embodiments, the program information comprises a starting address of the resistive memory in which the data is to be stored and a number of words in the data.

In certain embodiments, performing the first read operation comprises searching a buffer for the program information upon determining that the cache memory is filled and the buffer is not empty.

In certain embodiments, performing the first read operation further comprises storing read information of the data into the buffer to be linked with the program information upon determining that the program information is stored in the buffer.

In certain embodiments, performing the first read operation further comprises searching the cache memory using a fully-associated method based on the starting address and the number of words upon determining that the program information is not stored in the buffer.

In certain embodiments, performing the first read operation further comprises storing read information of the data to be linked with the program information into the cache memory when the program information is in the cache memory, and reading the data from the resistive memory when the program information is not in the cache memory.

According to another embodiment of the inventive concept, a resistive memory device comprises a memory controller, a resistive memory, and a cache memory. The memory controller is configured to perform a first read operation to read requested data from the cache memory during a program-to-active time during which the data is being programmed in the phase change random access memory, and further configured to perform a second read operation to read the requested data from the phase change memory after the program-to-active time.

According to still another embodiment of the inventive concept, a memory system comprise a host system comprising first and second buffers, a resistive memory device comprising a memory controller and a phase change random access memory, and a cache memory. The memory controller is configured to read data from the cache memory during a program-to-active time in which the data is being programmed in the phase change random access memory, and is further configured to read the data from the phase change random access memory after the program-to-active time, and wherein the host system is configured to determine whether the cache memory is full, and upon determining that the cache memory is full, reads program information from a first buffer and stores read information corresponding to the program information in a second buffer.

### BRIEF DESCRIPTION OF THE DRAWINGS

The attached drawings illustrate selected embodiments of the inventive concept. In the drawings, like reference numbers denote like features.

FIG. 1 is a block diagram illustrating a memory system according to an embodiment of the inventive concept.

FIG. 2 is a diagram illustrating an example of a variable resistance element of a resistive memory.

FIG. 3 is a diagram illustrating phase change characteristics of a variable resistance element.

FIG. 4 is a diagram illustrating currents applied to the variable resistance elements of FIG. 2 to control the phase change characteristics of FIG. 3.

FIG. 5 is a diagram illustrating an example of an information structure for data caching where a cache memory is not filled.

FIG. 6 is a diagram illustrating an example of an information structure for storing data in a temporary buffer where the cache memory is filled.

FIG. 7 is a flowchart illustrating a method of processing data for a resistive memory device according to an embodiment of the inventive concept.

FIG. 8A is a flowchart illustrating an example of performing a write operation to store data and program information in a resistive memory device.

FIG. 8B is a flowchart illustrating another example of performing a write operation to store data and program information in a resistive memory device.

FIG. 9 is a flowchart illustrating an example of performing a first read operation to read program information for data caching in a resistive memory device.

FIG. 10 is a flowchart illustrating an example of providing read information to a cache memory.

FIG. 11 is a diagram illustrating an example of an information structure for address caching where a cache memory is not filled.

FIG. 12 is a diagram illustrating an example of an information structure for address caching where a cache memory is filled.

FIG. 13 is a flowchart illustrating an example of performing a first read operation to read program information for address caching in a resistive memory device.

FIG. 14 is a flowchart illustrating an example of providing read information to a resistive memory.

FIG. 15 is a diagram illustrating an example of data caching.

FIG. 16 is a block diagram illustrating a memory system according to an embodiment of the inventive concept.

### DETAILED DESCRIPTION OF EMBODIMENTS

Embodiments of the inventive concept are described below with reference to the accompanying drawings. These embodiments are presented as teaching examples and should not be construed to limit the scope of the inventive concept.

In the description that follows, the terms first, second, third etc. may be used to describe various elements, but these elements should not be limited by these terms. Rather, these terms are used to distinguish one element from another. Thus, a first element discussed below could be termed a second element without departing from the teachings of the inventive concept. As used herein, the term “and/or” encompasses any and all combinations of one or more of the associated listed items.

Where an element is referred to as being “connected” or “coupled” to another element, it can be directly connected or coupled to the other element or intervening elements may be present. In contrast, where an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the inventive concept. As used herein, the singular forms “a,” “an” and “the” are intended to encompass the plural forms as well, unless the context clearly indicates otherwise. The terms “comprises,” “comprising,” “includes,” and/or “including,” where used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a block diagram illustrating a memory system 100 according to an embodiment of the inventive concept.

Referring to FIG. 1, memory system 100 comprises a host 110 and a resistive memory device 160. Resistive memory device 160 comprises a memory controller 130 and a resistive memory 150, and memory controller 130 comprises a cache memory 140 for compensating resistance drift during a program-to-active time (tPTA).

The program-to-active time corresponds to a delay time between a program operation and an active operation, such as a read operation. For instance, the program-to-active time can represent an interval between a time when data to be stored is provided to resistive memory 150 and a time when the stored data is ready to be read from resistive memory 150 by memory controller 130.

Host 110 typically comprises a central processing unit (CPU), a driver and an operating system (OS) and provides commands, addresses, and data to be stored in resistive memory device 160.

Resistive memory device 160 performs a write operation to store the data in resistive memory 150 and to store program information of the data into cache memory 140. The program information typically comprises both the data to be stored in resistive memory 150 and other information such as an address where the data is to be stored.

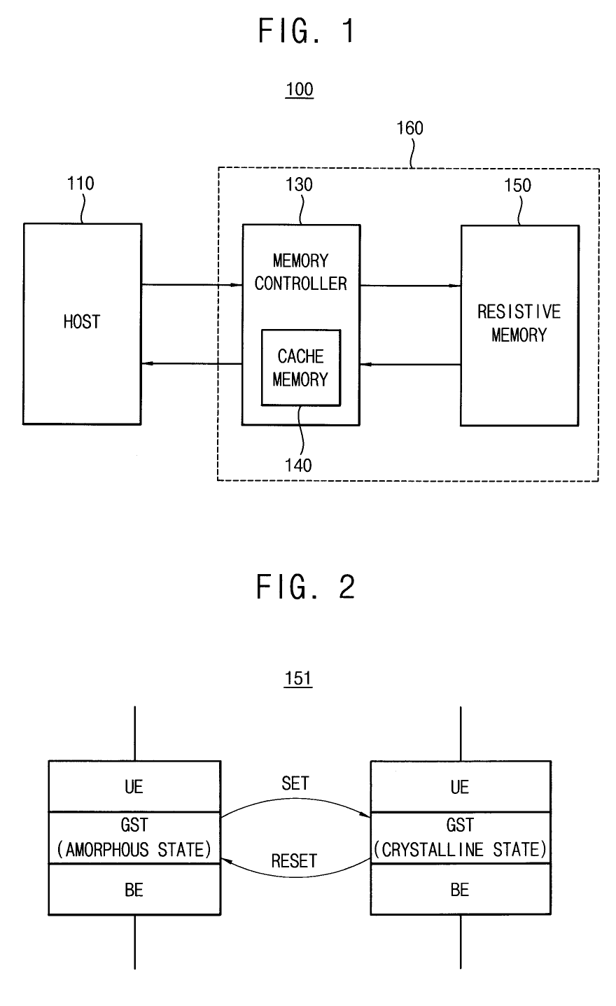

During the program-to-active time of the write operation, the data provided to resistive memory 150 cannot be read out of resistive memory 150 because storage of the data is not completed until after the program-to-active time. Storage of the data in resistive memory 150 is only completed once selected resistive memory cells have undergone an appropriate phase change as described below with reference to FIGS. 2-4. Following the phase change, resistive memory 150 is ready to provide the data to memory controller 130 or other components in a read operation.

During the program-to-active time, however, the data provided to resistive memory 150 can be read from data cache 140. For instance, during the program-to-active time of resistive memory 150, memory controller 130 can read the data from the program information stored in cache memory 140 instead of reading the data from resistive memory 150.

In some embodiments, resistive memory device 160 performs a first read operation during the program-to-active time to read the data from cache memory 140. Where resistive memory device 160 is unable to read the data from cache memory 140 during this time, it performs a second read operation to read the data from resistive memory 150 after the program-to-active time.

Resistive memory device 160 has a write operation mode and a read operation mode for performing different operations. For instance, the above-described write operation is performed during the write operation mode to store data and program information in resistive memory 150. In addition, the first read operation is performed during the write operation mode to read the data from cache memory 140. The second read operation is performed during the read operation mode to read the data from resistive memory 150.

Resistive memory 150 stores the data during the write operation mode and outputs the data during the read operation mode. Memory controller 130 provides host 110 with the data read from resistive memory 150.

In the write operation mode, host 110 provides a program signal, such as a write command, to memory controller 130 to store the data in resistive memory 150. Memory controller 130 performs the write operation in response to the write command and stores program information for the data in cache memory 140. In the read operation mode, host 110 accesses the program information in cache memory 140 to read the data during the program-to-active time. Cache memory 140 can comprise, for instance, an SRAM or a DRAM.

FIG. 2 is a diagram illustrating an example of a variable resistance element of a resistive memory.

Referring to FIG. 2, the variable resistance element comprises a phase change material GST disposed between a first electrode UE and a second electrode BE. Phase change material GST assumes an amorphous state or a crystalline state in response to temperature changes produced by an applied current. Phase change material GST exhibits different resistances in the amorphous and crystalline states. An example of phase change material GST is GeₓSb_{y}Te_{z}.

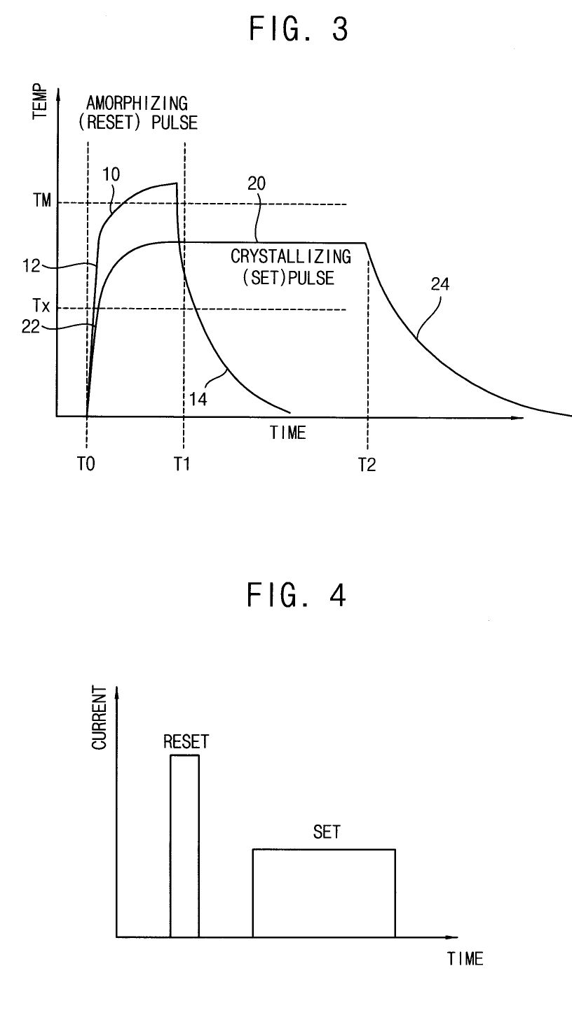

FIG. 3 is a diagram illustrating phase change characteristics of a variable resistance element. In FIG. 3, a horizontal axis TIME indicates time and a vertical axis TEMP indicates temperature.

Referring to FIG. 3, temperature changes 10, 12 and 14 represent conditions for placing phase change material GST in the amorphous state, and temperature changes 20, 22, 24 represent a conditions for placing phase change material GST in the crystalline state.

Phase change material GST is placed in the amorphous state by heating it above a melting temperature TM and then rapidly cooling it during an interval T0-T1. Phase change material GST is placed in the crystalline state by heating it above a crystallization temperature Tx during an interval T0-T2 and then cooling it thereafter. For example, the write operation mode may comprise a set operation mode and a reset operation mode.

An operating mode of a resistance memory device for changing the variable resistance element from the amorphous state to the crystalline state can be referred to as a “set mode”, and an operating mode for changing the variable resistance element from the crystalline state to the reset state can be referred to as a “reset mode”.

FIG. 4 is a diagram illustrating currents applied to the variable resistance elements of FIG. 2 to achieve the phase change characteristics of FIG. 3. In FIG. 4, a horizontal axis TIME indicates time and a vertical axis CURRENT indicates current.

Referring to FIG. 4, a current level of a reset pulse RESET is higher in magnitude than a current level of a set pulse SET, and a duration time of reset pulse RESET is shorter than a duration time of set pulse SET. The current level of set pulse SET and the current level of reset pulse RESET indicate amplitudes of current for storing data “1” and “0”, respectively, during the write operation mode. In the write operation mode, the set mode can be used to achieve a relatively lower resistance state in a variable resistance element, and the reset mode can be used to achieve a relatively higher resistance in a variable resistance element.

The time required to change the states of the variable resistance elements leads to resistance drift. However, in certain embodiments of the inventive concept, a cache memory is used to compensate for the resistance drift. For instance, in the embodiment of FIG. 1, cache memory 140 is provided in memory controller 130 to compensate for the resistance drift.

In the embodiment of FIG. 1, host 110 or resistive memory device 160 performs a write operation to store data in resistive memory 150 using memory controller 130, and to store program information for the data in cache memory 140. Then, host 110 or resistive memory device 160 performs a first read operation to read the program information from cache memory 140 during the program-to-active time without waiting until the data is stored in resistive memory 150.

Where cache memory 140 is filled or has substantially no storage space to store the program information, host 110 stores the program information in a buffer of host 110. Otherwise, where cache memory 140 is not filled, host 110 or memory controller 130 stores the program information in cache memory 140.

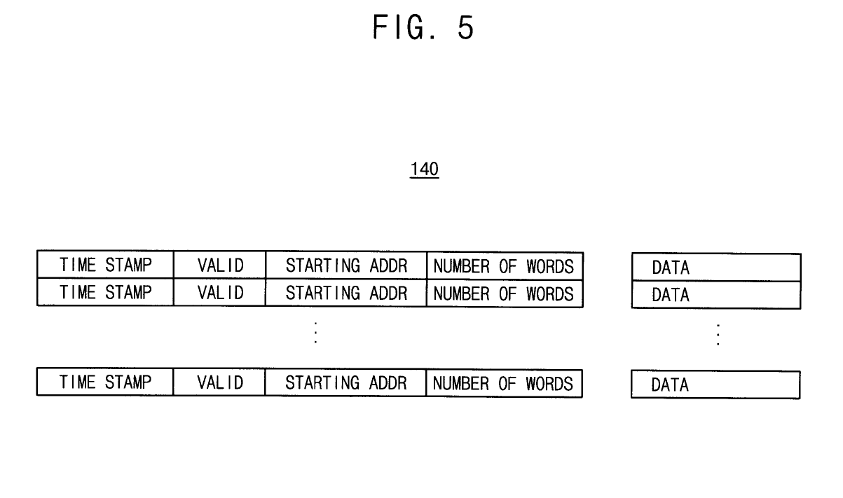

FIG. 5 is a diagram illustrating an example of an information structure for storing program information in cache memory 140.

Referring to FIG. 5, the information structure comprises a TIME STAMP field, a VALID field, a STARTING ADDR field, a NUMBER OF WORDS field, and a DATA field. The TIME STAMP field comprises a counter value that begins to increase when the program information is stored in cache memory 140. The program information expires when the counter value reaches a value corresponding to the program-to-active time. The VALID field comprises a valid bit that assumes a value “1” when the program information is first stored in cache memory 140 and assumes a value “0” when the time stamp expires. The STARTING ADDR field comprises a starting address of resistive memory 150 where data corresponding to the program information is to be stored. The NUMBER OF WORDS field comprises a number of words to be programmed, and a DATA field comprises the data.

A data caching operation of memory system 100 can be performed using the information structure of FIG. 5, as explained below.

Referring to FIGS. 1 and 5, in the write operation mode of memory system 100, host 110 or memory controller 130 performs a write operation to store the program information in an empty row of cache memory 140 where valid bit VALID is “0”, and to store corresponding data into a memory cell array of resistive memory 150.

Where cache memory 140 is filled, the program information is not stored therein, and a cache full signal is transmitted to host 110. Upon receiving the cache full signal, host 110 stores the program information in a first buffer. Upon expiration of a time stamp of an existing entry of cache memory 140, host 110 transfers an oldest entry of program information stored in the first buffer to cache memory 140 to replace the expired cache entry. In other words, whenever cache memory 140 has an empty slot (e.g., due to expiration of an existing cache entry), host 110 provides an entry of program information stored in the first buffer, using a first-in first-out (FIFO) method.

In some embodiments, data is not programmed in resistive memory 150 until corresponding program information is stored in cache memory 140. For instance, memory system 100 may wait until the program information is transferred from the first buffer to cache memory 140 before storing the data in resistive memory 150. In other embodiments, the data can be programmed in resistive memory 150 even if the program information is not stored in cache memory 140.

In the read operation mode of memory system 100, host 110 first determines whether cache memory 140 is filled and whether the first buffer is non-empty. Upon determining that cache memory 140 is filled and the first buffer is non-empty, host 110 searches the first buffer to identify program information corresponding to data to be read in the read operation mode. Where the program information is identified in the first buffer, host 110 stores read information for the read operation in a second buffer. The read information can be used in subsequent operations, for instance, to indicate to cache memory 140 that the data corresponding to the program information has been the target of a read operation. Accordingly, the read information can be used to inform future caching decisions and other operations.

Where the program information is not identified in the first buffer, host 110 or resistive memory device 160 searches for the program information in cache memory 140 using a fully-associative method (i.e., a method that assumes a fully associative cache) based on a starting address STARTING ADDR and a number of words included in the read information. If the search identifies the program information in cache memory 140, memory controller 130 reads the data from among the program information. On the other hand, memory controller 130 can read the data from resistive memory 150 upon determining that the program information is not stored in cache memory 140.

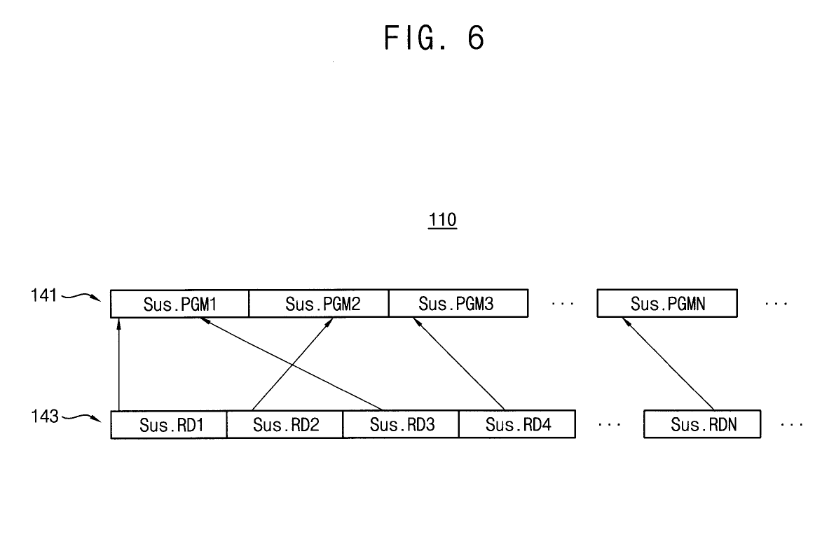

FIG. 6 is a diagram illustrating an example of an information structure for storing data in first and second buffers of host 110 when cache memory 140 is filled. The data stored in the first and second buffers of host 110 is referred to as “sustained” data because it remains outside of cache 140.

Referring to FIG. 6, sustained program information Sus.PGM1 through Sus.PGMN is stored in a first buffer 141 of host 110, and sustained read information Sus.RD1 through Sus.RDN is stored in a second buffer 143 of host 110.

In the write operation mode of memory system 100, where cache memory 140 is filled or has substantially no storage space to store program and read information, program information is stored in first buffer 141 as sustained program information. Upon expiration of a program information entry in cache memory 140, an oldest entry of sustained program information Sus.PGM1 through Sus.PGMN stored in the first buffer is transferred to cache memory 140. In other words, whenever cache memory 140 is not filled, host 110 transfers an entry of sustained program information Sus.PGM1 through Sus.PGMN from first buffer 141 to cache memory 140 using a FIFO method.

In some embodiments, data is not programmed in resistive memory 150 until corresponding sustained program information is stored in cache memory 140. In other embodiments, the data can be programmed in resistive memory 150 even if the sustained program information is not stored in cache memory 140.

Sustained read information Sus.RD1 through Sus.RDN is linked with the sustained program information Sus.PGM1 through Sus.PGMN as indicated by arrows in the example of FIG. 6. In the example of FIG. 6, sustained read information Sus.RD1 and Sus.RD3 correspond to sustained program information Sus.PGM1, and so on. In other words, sustained read information Sus.RD1 and SusRD3 indicate that sustained program information Sus.PGM1 has been read twice from first buffer 141. The sustained read information can be used in subsequent operations, for instance, to indicate to cache memory 140 that the data corresponding to the sustained program information has been the target of read operations. Accordingly, the sustained read information can be used to inform future caching decisions and other operations.

Where sustained program information Sus.PGM1 through Sus.PGMN in first buffer 141 is provided to cache memory 140, corresponding sustained read information that remains in the first buffer can be output in order and then removed from second buffer 143. For example, where sustained program information Sus.PGM1 is provided to cache memory 140, sustained read information Sus.RD1 and Sus.RD3 can be output in order and then removed from second buffer 143 while the other sustained read information Sus.RD2 and Sus.RD4 through Sus.RDN is rearranged based on the removal of read information Sus.RD1 and Sus.RD3.

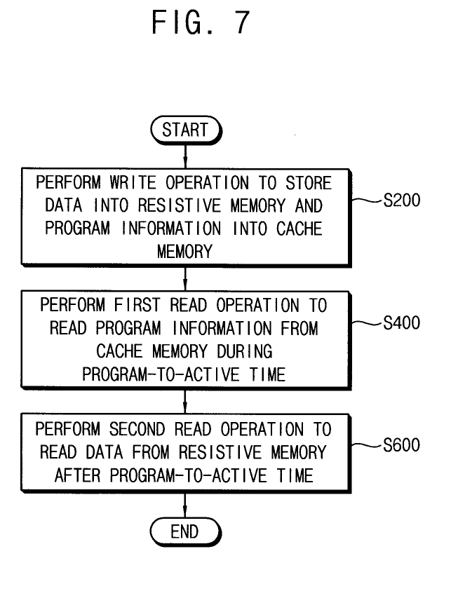

FIG. 7 is a flowchart illustrating a method of processing data for a resistive memory device according to an embodiment of the inventive concept. In the description that follows, example method steps are indicated by parentheses (SXXX).

Referring to FIGS. 1 and 7, the method comprises performing a write operation to store data in resistive memory 150 and to store program information corresponding to the data in cache memory 140 (S200). The method further comprises performing a first read operation to read the program information from cache memory 140 during a program-to-active time (tPTA) (S400), and performing a second read operation to read the data from resistive memory 150 after the program-to-active time if the program information is not read from cache memory 140 during the program-to-active time (S600). By using this method, memory system 100 can read the data during the program-to-active time, thereby reducing the effects of resistance drift.

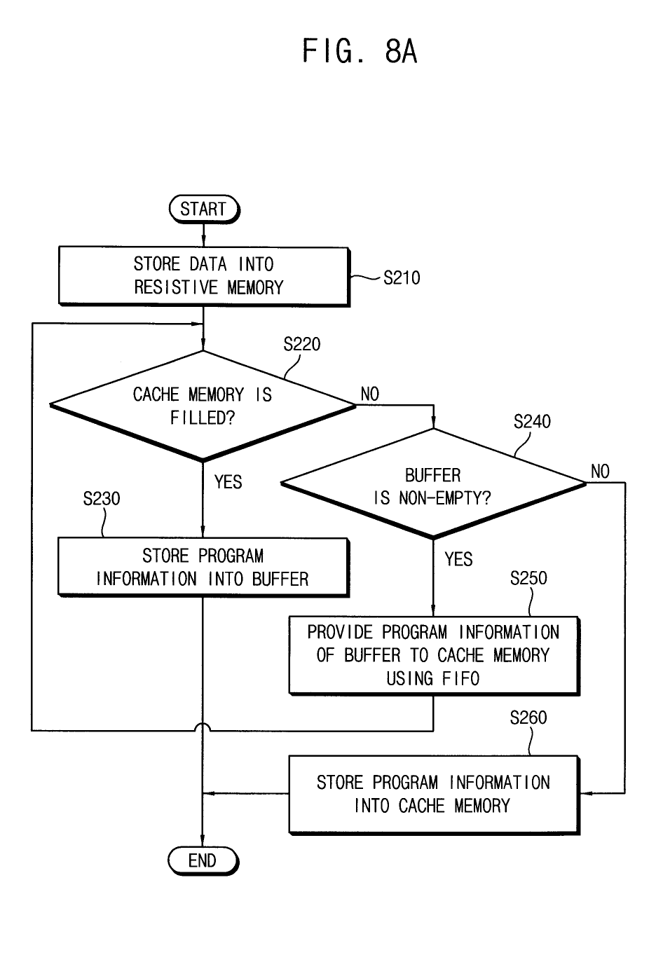

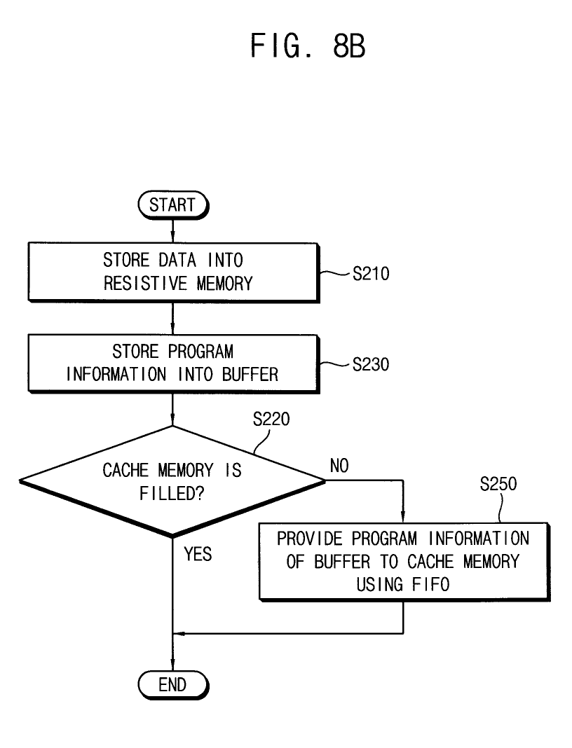

FIG. 8A is a flowchart illustrating an example of performing a write operation to store first data and first program information in a resistive memory device. The method of FIG. 8A can be used to implement step S200 of FIG. 7.

Referring to FIGS. 1 and 8A, the data is stored in resistive memory 150 of resistive memory device 160 (S210). Then, if cache memory 140 is filled (S220=YES), the program information is stored in a first buffer of host 110 (S230). Otherwise, if cache memory 140 is not filled (S220=NO) and the first buffer is non-empty (S240=YES), the program information stored in the first buffer is provided to cache memory 140 using a FIFO method (S250). Otherwise, if cache memory 140 is not filled (S220=NO) and the first buffer is not non-empty (S240=NO), the program information is stored in cache memory 140 (S260).

FIG. 8B is a flowchart illustrating another example of performing a write operation to store first data and first program information in a resistive memory device. Like the method of FIG. 8A, the method of FIG. 8B can also be used to implement step S200 of FIG. 7.

Referring to FIGS. 1 and 8B, the data is stored in resistive memory 150 of resistive memory device 160 (S210), and the program information is stored in a first buffer of host 110 (S230). Where cache memory 140 is not filled (S220=NO), the program information is transferred from the first buffer to cache memory 140 using a FIFO method (S250).

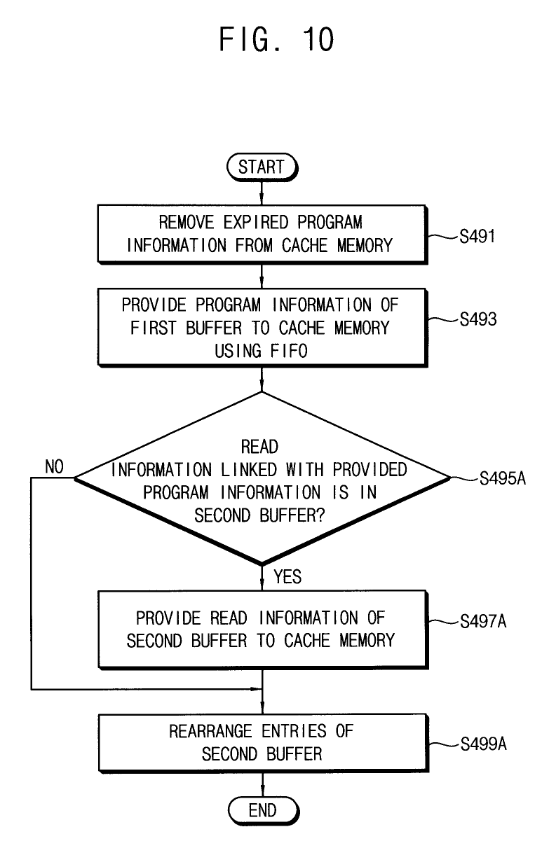

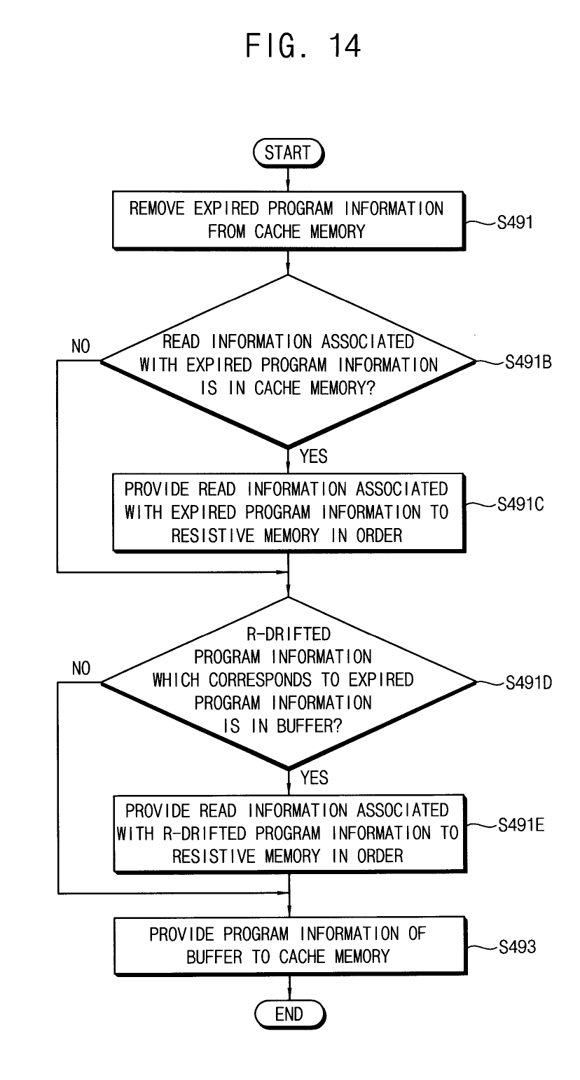

As will be described with reference to FIGS. 10 and 14, the first program information in the first buffer can be provided to cache memory 140 using the FIFO method to fill cache memory 140 with new entries as time stamps of existing cache entries expire.

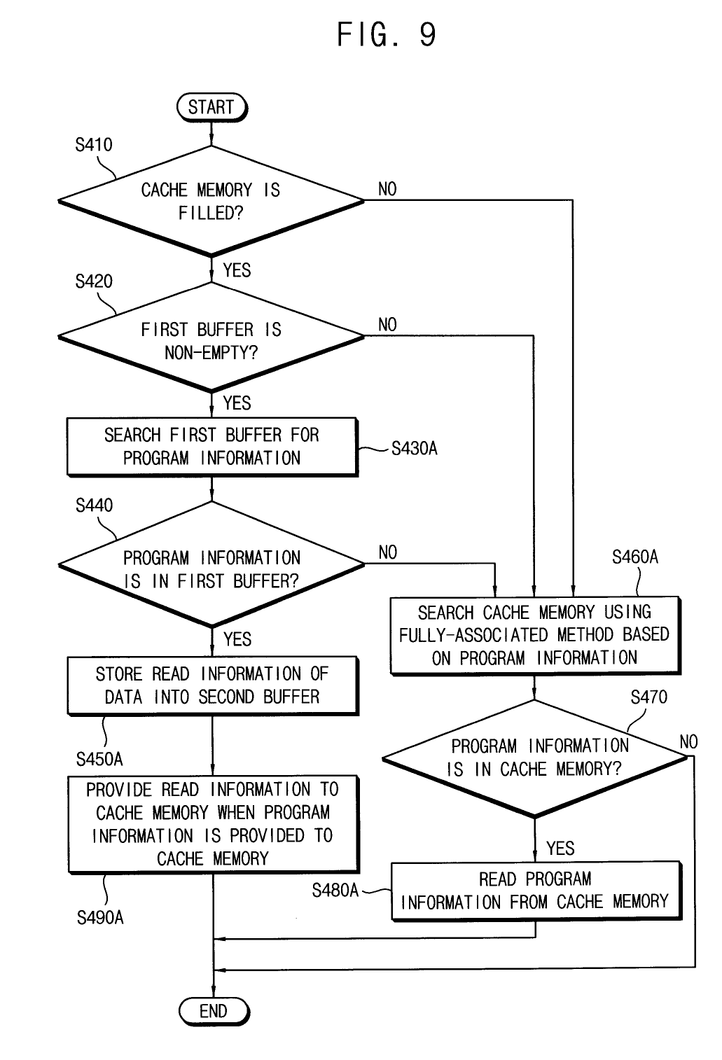

FIG. 9 is a flowchart illustrating an example of performing a first read operation to read program information for data caching in resistive memory device 150.

Referring to FIGS. 5, 7 and 9, upon initiation of the read operation, memory system 100 determines whether where cache memory 140 is filled (S410). Upon determining that cache memory 140 is filled (S410=YES) and a first buffer of host 110 is non-empty (S420=YES), the first buffer is searched for the program information (S430A).

Upon completing step S430A, the method determines whether the program information is stored in the first buffer (S440). Upon identifying the program information in the first buffer (S440=YES), the method stores read information related to the program in a second buffer of host 110 (S450A). The read information is subsequently transferred to cache memory 140 to indicate that the program data has been read in a read operation. Accordingly, the read information can be used, for instance, to inform a caching algorithm that may be performed by cache memory 140. The read information is typically transferred from the second buffer to cache memory 140 when the program information is provided to cache memory 140 (S490A). Where the program information is identified in the first buffer (S440=YES), the corresponding data is not stored in resistive memory 150 until the program information is transferred to cache memory 140.

Upon determining that the program information is not stored in the first buffer (S440=NO), cache memory 140 is searched for the program information using a fully-associated method (S460A). Where the program information is identified in cache memory 140 (S470=YES), the program information is read from cache memory 140 (S480A). On the other hand, where the program information is not identified in cache memory 140 (S470=NO), the data may be read from the resistive memory after the program-to-active time (S600).

Cache memory 140 may be searched using a fully-associated method based on the starting address and the number of words (S460A) when the program information is not sustained in the first buffer (S410=NO, S420=NO or S440=NO). The program information may comprise the starting address, the number of words and the data.

FIG. 10 is a flowchart illustrating an example of providing read information to a cache memory.

Referring to FIG. 10, expired program information is removed from cache memory 140 (S491). Program information stored in the first buffer is then provided to cache memory 140 using a FIFO method to replace the expired program information (S493). Where read information which is linked with the program information and stored in the second butter (S495A=YES), the read information in the second buffer is provided to cache memory 140 and removed from the second buffer (S497A). Finally, remaining entries of the second buffer are rearranged based on the removal of the read information (S499A).

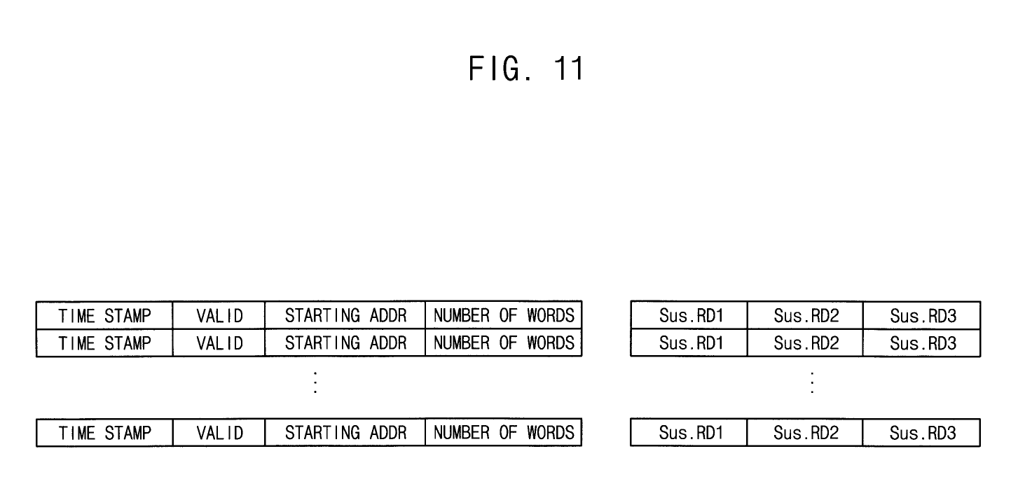

FIG. 11 is a diagram illustrating an example of an information structure used for address caching where cache memory 140 is not filled.

Referring to FIG. 11, the information structure comprises a TIME STAMP field, a VALID field, a STARTING ADDR field, and a NUMBER OF WORDS field. The TIME STAMP field comprises a counter value that begins to increase when the read information is stored in cache memory 140, and expires when the counter value reaches a program-to-active time (tPTA). The VALID field indicates a valid bit which has a value “1” when the new entry is provided and a value “0” when the time stamp expires. The STARTING ADDR field indicates a starting address of resistive memory 150 in which data corresponding to the information structure is to be stored. The NUMBER OF WORDS field indicates a number of words in the data to be programmed.

Compared with the information structure for data caching illustrated in FIG. 5, the information structure of FIG. 11 comprises sustained read information instead of the cached data. Thus, the read information of the data may be further stored in cache memory 140 to be linked with the program information.

Referring to FIG. 1 and FIG. 11, an operation of address caching will be described.

Address caching of memory system 100 of FIG. 1 is similar to data caching except that the cached data is not stored in cache memory 140 during a program mode and thus the data to be read may be read from the program information of the data stored in cache memory 140, but may be read from resistive memory 150 using the number of words and the starting address of resistive memory 150 where the data is to be stored.

Host 110 or resistive memory device 160 can store a new entry of program information at an empty row in where VALID field is “0” and perform a program operation for storing data of the new entry into resistive memory 150.

Where cache memory 140 is filled, a program operation is not performed and a cache full signal is transmitted to host 110 or memory controller 130. Host 110 typically has a buffer for storing or queuing sustained program information. At least one entry of the sustained program information stored in the buffer can be provided to cache memory 140 when the time stamp of the entry of program information is expired in cache memory 140. In other words, where cache memory 140 is not filled, host 110 can provide entries of the program information sustained in the buffer using a FIFO method to store the program information into cache memory 140. After the time stamp of an entry of program information expires, the entry is removed from cache memory 140. In other example embodiments, the program operation for resistive memory 150 may be performed even though cache memory 140 is filled.

During the first read operation, an operation of address caching of memory system 100 of FIG. 1 can be performed as follows.

Where cache memory 140 is filled and the buffer of host 110 is non-empty, host 110 searches the first buffer. Where the program information of the data to be read is in the first buffer, host 110 stores or buffers corresponding read information of the data into the second buffer. On the other hand, where the program information of the data to be read is not in the first buffer, host 110 or memory controller 130 searches cache memory 140 using a fully-associative method based on a starting address and number of words of the data. Once cache memory 140 stores the program information of the data to be read, host 110 or resistive memory device 150 stores the corresponding read information in cache memory 140. Memory controller 130 can read the data from resistive memory 150 where cache memory 140 does not comprise the program information of the data to be read, i.e., after the program-to-active time.

Where the time stamp of FIG. 11 expires, the sustained read information Sus.RD1 to Sus.RD3 stored in each row of cache memory 140 is provided to resistive memory 150 in order, and then the valid bit is set to “0”.

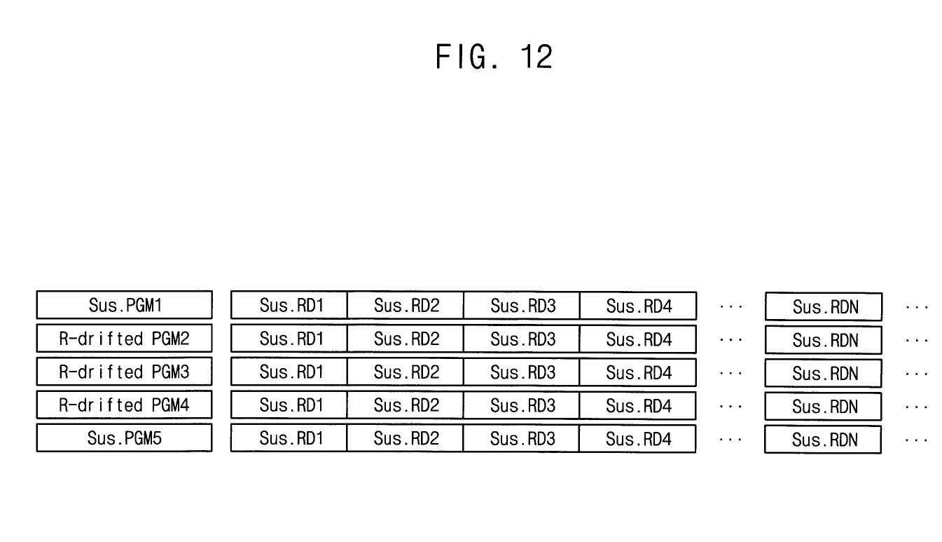

FIG. 12 is a diagram illustrating an example of an information structure used for address caching where cache memory 140 is filled.

In the example of FIG. 12, sustained program information Sus.PGM1 and Sus.PGM5, and resistance drift program information R-drifted PGM2, R-drifted PGM3, and R-drifted PGM4 are be stored in the buffer as will be described below. Sustained read information Sus.RD1 to Sus.RDN is also stored in a buffer where the program information is stored.

Where cache memory 140 is filled, program information of the data to be programmed is stored in the buffer. Otherwise, where cache memory 140 is not filled, host 110 provides an uppermost entry of sustained program information to cache memory 140. Then, the sustained read information Sus.RD1 to Sus.RDN are associated with the program information is stored to cache memory 140 in order.

Resistance drifted (R-drifted) program information can be incorporated in the buffer for storing additional read information of the cached data in cache memory 140. After the time stamp is expired, host 110 can search the R-drifted program information R-drifted PGM2, R-drifted PGM3, and R-drifted PGM4 in the buffer for the expired program information. Where the R-drifted program information that corresponds to the expired program information is in the buffer, host 110 can provide resistive memory 150 with the sustained read information Sus.RD1 through Sus.RDN that is associated with the R-drifted program information of the buffer after providing resistive memory 150 with associated read information stored in cache memory 140.

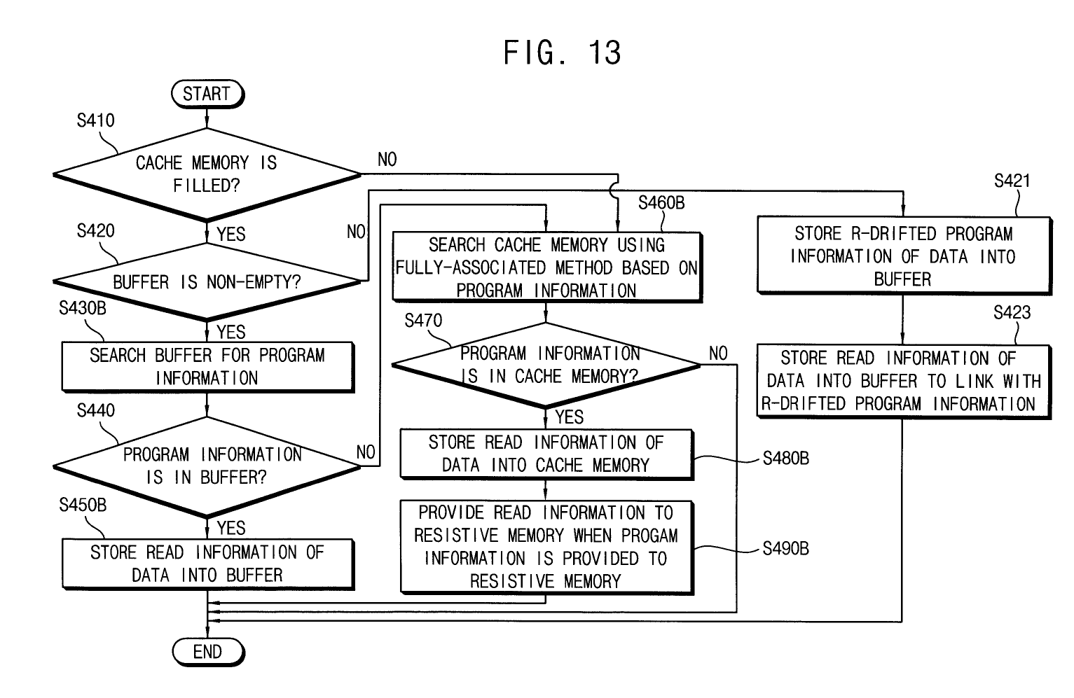

FIG. 13 is a flowchart illustrating an example of performing a first read operation to read program information for address caching in a resistive memory device.

Referring to FIG. 13, the buffer is searched for the program information (S430B) where cache memory 140 is filled (S410=YES) and the buffer is non-empty (S420=NO).

The read information of the data is stored in the buffer to be linked with the program information (S450B) where the program information is sustained in the buffer (S440=YES).

Cache memory 140 is searched using a fully-associated method based on the starting address and the number of words (S460B) where the program information is not sustained in the buffer (S440=NO or S410=NO). The program information typically comprises a starting address and number of words of the data.

The read information of the data is stored to link with the program information in cache memory 140 (S480B) when the program information is in cache memory 140 (S470=YES). The read information of the data is provided to resistive memory 150 for reading the data when the program information is provided to resistive memory 150 (490B). The data can be read from resistive memory 150 after the program-to-active time (S600) when the program information is not in the cache memory 150 (S470=NO).

Where the cache memory is filled (S410=YES) and the buffer is empty (S420=NO), no more read information associated with the program information can be stored in cache memory 140. Thus, R-drifted program information of the data is stored into the buffer (S421) and read information of the data is stored in the buffer to be linked with the R-drifted program information (S423).

FIG. 14 is a flowchart illustrating an example of providing read information to a resistive memory.

Referring to FIG. 14, where a time stamp of a program information is expired, the expired program information is output or removed from cache memory 140 (S491). Where read information associated with the expired program information is in cache memory 140 (S491B=YES), the read information is provided to resistive memory 150 in order (S491C). Where R-drifted program information that corresponds to the program information is in the first buffer of host 110 (S491D=YES), read information associated with the R-drifted program information is provided to resistive memory 150 in order (S491E). The program information in the first buffer is provided to cache memory 140 (S493).

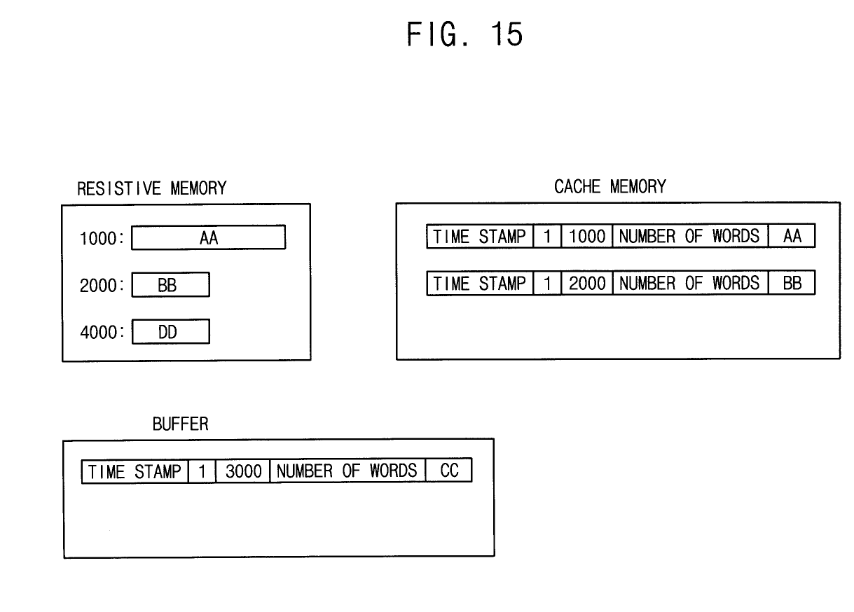

FIG. 15 is a diagram illustrating an example of data caching.

Referring to FIG. 15, data AA, BB, and DD are stored at addresses 1000, 2000 and 4000 of resistive memory 150. Data AA and BB are also stored in cache memory 140. Where cache memory 140 is filled, program information of data CC at an address 3000 is stored in the first buffer of host 110. Program information of address 3000 which is stored in the first buffer of host 110 is stored into cache memory 140 after cache memory 140 secures storage space by removing an entry of expired program information.

In a conventional resistive memory device, such as a PRAM, an active operation such as a read operation cannot be performed until after a program operation because of resistance drift. Thus, the conventional memory system employing the resistive memory cannot be read data during a program-to-active time.

To compensate for the degradation of operation speed caused by resistance drift, resistive memory 150 according to certain embodiments can, during the program-to-active time, read program information of data from cache memory 140 that is located outside resistive memory 150, instead of reading the data from resistive memory 150. Referring to FIG. 15, host 110 or memory controller 130 can read data DD of address 4000 from resistive memory 150. However, host 110 or memory controller 130 can read data AA and BB which are stored at address 1000 and 2000, respectively, not from resistive memory 150 but from cache memory 140 by reading program information of the data AA and BB, when data caching is employed.

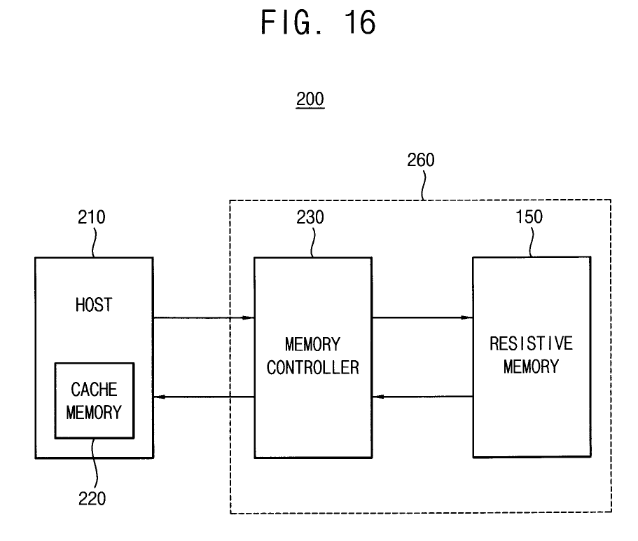

FIG. 16 is a block diagram illustrating a memory system according to some embodiments of the inventive concept.

Referring FIG. 16, memory system 200 comprises a host 210 and a resistive memory device 260. Resistive memory device 260 comprises a memory controller 230 and a resistive memory 150. Host 210 comprises a cache memory 220. Cache memory 220 can store a driver or an operating system (OS) of host 210.

Host 210 comprises a CPU, the driver, and the OS and provides commands, addresses and data. Memory controller 230 provides the commands, the addresses, and the data to resistive memory 150. Resistive memory device 260 stores the data in resistive memory 150 or provides the data read from resistive memory 150. Memory controller 230 provides host 210 with the data provided from resistive memory 150.

Host 210 performs a write operation to store the data into resistive memory 150 and to store program information of the data into cache memory 220. Host 210 performs a first read operation to read the program information of the data from cache memory 220 of host 210 during a program-to-active time without waiting until the data is stored completely into resistive memory 150. Host 210 performs a second read operation to read the data from resistive memory 150 after the program-to-active time. Cache memory 220 can comprise, for instance, an SRAM or a DRAM.

Cache memory 220 stores the driver or the OS of memory system 200. Thus, the effect of resistance drift can be reduced and the operation speed of the memory device can be increased by using cache memory 220 for reading data during a program-to-active time.

Referring to FIG. 16, host 210 performs a write operation to store the data into resistive memory 150 through memory controller 230, and to store program information of the data into cache memory 220 disposed in host 210. Host 210 performs a first read operation to read the program information of the data from cache memory 220 through memory controller 230 instead of reading the data from resistive memory 150 through memory controller 230 during the program-to-active time. Host 210 performs a second read operation to read the data from resistive memory 150 through memory controller 230 after the program-to-active time.

Where cache memory 220 is filled, host 210 stores the program information of the data into a buffer of host 210. Otherwise, where cache memory 220 is not filled, host 210 stores the program information of the data into cache memory 220.

The operation of memory system 200 is similar to operation of memory system 100 of FIG. 1, and thus a repeated description will be omitted.

The write operation, the first or second read operation described with reference to FIG. 7, 8A, 8B, 9, 10, 13 or 14 can be performed by the host or the resistive memory device of FIG. 1 or 16. In addition, such operations may be performed by other circuitry in or out of the resistive memory device.

As indicated by the foregoing, methods of data processing according to example embodiments may be employed by various memory systems such as memory systems of FIGS. 1 and 16. In addition, the inventive concept can be embodied in systems such as microprocessor systems, digital signal processors, communication system processors, or other systems that perform write and read operations, as well as in embedded memory systems.

Although a memory system for storing and reading data in and from a resistive memory has been mainly described above, example embodiments can be adapted for various memory systems comprising a resistive memory such as PRAM.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. A method of processing data in a resistive memory device comprising a resistive memory, the method comprising:
performing a write operation to store data into the resistive memory and to store program information corresponding to the data into a cache memory;
performing a first read operation to read the program information from the cache memory during a program-to-active time in which the data is being stored in the resistive memory; and
performing a second read operation to read the data from the resistive memory after the program-to-active time.

2. The method of claim 1, wherein the cache memory is incorporated in a memory controller of the resistive memory device.

3. The method of claim 1, wherein the cache memory is incorporated in a host.

4. The method of claim 1, wherein the cache memory is a dynamic random access memory (DRAM) or a static random access memory (SRAM).

5. The method of claim 1, wherein the resistive memory is a phase-change random access memory (PRAM).

6. The method of claim 1, wherein performing the write operation comprises:
determining whether the cache memory is filled;
upon determining that the cache memory is filled, storing the program information into a buffer; and
upon determining that the cache memory is not filled, storing the program information into the cache memory.

7. The method of claim 1, wherein performing the write operation comprises:
determining whether the cache memory is filled;
upon determining that the cache memory is filled, storing the program information into a buffer;
detecting expiration of an entry in the cache memory; and
upon detecting the expiration of the entry, transferring the program information from the buffer to the cache memory.

8. The method of claim 7, wherein the program information is transferred from the buffer to the cache memory using first-in first-out (FIFO) method.

9. The method of claim 1, wherein the program information comprises a starting address of the resistive memory in which the data is to be stored, a number of words in the data, and the data.

10. The method of claim 9, wherein performing the first read operation comprises:
determining whether the cache memory is filled and whether a first buffer is empty; and
upon determining that the cache memory is filled and the first buffer is not empty, searching the first buffer for the program information.

11. The method of claim 10, wherein performing the first read operation further comprises:
determining whether the program information is stored in the first buffer; and
upon determining that the program information is stored in the first buffer, storing read information for the data in a second buffer.

12. The method of claim 10, wherein performing the first read operation further comprises:
determining whether the program information is stored in the first buffer; and
upon determining that the program information is not stored in the first buffer, searching the cache memory for the program information using a fully-associated method based on the starting address and the number of words.

13. The method of claim 12, wherein performing the first read operation further comprises:
determining whether the program information is stored in the cache memory;
upon determining that the program information is stored in the cache memory, reading the program information from the cache memory; and
upon determining that the program information is not stored in the cache memory, reading the data from the resistive memory.

14. The method of claim 1, wherein the program information comprises a starting address of the resistive memory in which the data is to be stored and a number of words in the data.

15. The method of claim 14, wherein performing the first read operation comprises searching a buffer for the program information upon determining that the cache memory is filled and the buffer is not empty.

16. The method of claim 15, wherein performing the first read operation further comprises storing read information of the data into the buffer to be linked with the program information upon determining that the program information is stored in the buffer.

17. The method of claim 16, wherein performing the first read operation further comprises searching the cache memory using a fully-associated method based on the starting address and the number of words upon determining that the program information is not stored in the buffer.

18. The method of claim 17, wherein performing the first read operation further comprises:
storing read information of the data to be linked with the program information into the cache memory when the program information is in the cache memory; and
reading the data from the resistive memory when the program information is not in the cache memory.

19. A resistive memory device comprising a memory controller, a resistive memory, and a cache memory, wherein the memory controller is configured to perform a first read operation to read requested data from the cache memory during a program-to-active time during which the data is being programmed in the phase change random access memory, and further configured to perform a second read operation to read the requested data from the phase change memory after the program-to-active time.

20. A memory system comprising:
a host system comprising first and second buffers;
a resistive memory device comprising a memory controller and a phase change random access memory (PRAM); and
a cache memory;
wherein the memory controller is configured to read data from the cache memory during a program-to-active time in which the data is being programmed in the PRAM, and is further configured to read the data from the PRAM after the program-to-active time; and
wherein the host system is configured to determine whether the cache memory is full, and upon determining that the cache memory is full, reads program information from a first buffer and stores read information corresponding to the program information in a second buffer.
